(19) United States
(12) Patent Application Publication
(10) Pub. No.: US 2007/0152715 A1
(43) Pub. Date: Jul. 5, 2007

(54) LOCKED LOOP CIRCUIT FOR IMPROVING LOCKING SPEED AND CLOCK LOCKING METHOD USING THE SAME

(76) Inventor: Duk-Ha PARK, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/426,532

(22) Filed: Jun. 26, 2006

(30) Foreign Application Priority Data
Dec. 21, 2005 (KR) 10-2005-126556

(51) Int. Cl. H03D 13/00; G01R 25/00

(52) U.S. Cl. 327/3

(57) ABSTRACT

An improved locked loop circuit and method are provided. The circuit preferably includes an initialization and phase comparison unit to generate a first control signal according to a phase comparison of a feedback clock signal and the reference clock signal, a control voltage adjustment unit to generate a second control signal having a voltage level adjusted by the first control signal, and an oscillation unit to form an oscillation unit having delay stages selected from a plurality of delay stages, the delay stages locking the output clock signal to the reference clock signal. The oscillation unit further locks the output clock signal to the reference clock signal according to the voltage level of the second control signal.

### CROSS-REFERENCE TO RELATED APPLICATIONS

This U.S. non-provisional patent application claims priority under 35 U.S.C. § 119 of Korean Patent Application No. 10-2005-126556, filed on Dec. 21, 2005, the entire contents of which are hereby incorporated by reference.

### BACKGROUND OF THE INVENTION

1. Field of the Invention

This invention relates to electronic circuits and, more particularly, to an improved locked loop circuit and a clock locking method using the improved locked loop circuit.

2. Description of the Related Art

A locked loop circuit, such as a Phase-Locked Loop (PLL) or Delay-Locked Loop (DLL) circuit, is a circuit for generating an output clock signal locked to a received reference clock signal. By using the locked loop circuit, skew between data to be transmitted and a system clock signal can be reduced, thus improving the data transfer rate and system operating speed. Such a locked loop circuit has been widely used in frequency synthesizers provided in analog and digital communication systems and, more recently, in synchronous semiconductor memory devices.

Typically, locking an output clock signal to a reference clock signal includes sequentially performing a coarse locking procedure and a fine locking procedure. In the coarse locking procedure, the output clock signal is roughly locked to the reference clock signal. In the fine locking procedure, the output clock signal is precisely locked to the reference clock signal.

Generally, the time required for the output clock signal to be locked to the reference clock signal is relatively longer than the setup time of other internal circuits. Thus, when operations of other internal circuits are temporarily disabled in standby or power-down mode, the locked loop circuit may remain enabled in some instances. Accordingly, unnecessary power may be consumed. An improvement in the coarse locking speed and, consequently, the locking speed of the output clock signal can improve the operation speed of a system or semiconductor memory device and reduce power consumption.

FIG. 1 is a diagram of a conventional phase-locked loop (PLL) circuit. The PLL circuit includes a phase comparator 10, a charge pump 20, a loop filter 30, and a voltage controlled oscillator 40. The phase comparator 10 compares the phases of a feedback clock signal FCLK and a reference clock signal RCLK to generate a pumping control signal VPUMP having a logic state based on the comparison. The feedback clock signal FCLK is obtained by dividing the output clock signal OCLK through a divider 50. The charge pump 20 generates a charged or discharged output signal according to the logic state of the pumping control signal VPUMP. The loop filter 30 then passes the low frequency component of the output signal of the charge pump 20 to generate an oscillation control signal VCON. The voltage controlled oscillator 40, which includes a plurality of delay cells implemented in a chain structure (not shown in FIG. 1), generates the output clock signal OCLK. To control the frequency of the output clock signal OCLK and lock the output clock signal OCLK to the reference clock signal RCLK, the response delay time of the delay cells is controlled depending on the voltage level of the oscillation control signal VCON.

In the conventional PLL circuit of FIG. 1, both the coarse and fine locking of the output clock signal OCLK are performed by variations in the voltage level of the oscillation control signal VCON. Thus, to increase the coarse locking speed, the gain of the voltage control oscillator 40 can be increased. The gain is the ratio of variation in the response delay time of delay cells to variation in the voltage level of the oscillation control signal VCON. However, if the gain is increased, jitter of the output clock signal OCLK relative to the reference clock signal RCLK can also increase, and the fine locking speed is decreased. In this specification, the term “jitter” denotes a phase difference between two compared signals. Therefore, it is difficult to improve locking speed in the conventional locked loop circuit of FIG. 1.

### SUMMARY OF THE INVENTION

One aspect of the invention is a locked loop circuit for generating an output clock signal locked to a reference clock signal. The locked loop circuit includes an initialization and phase comparison unit to compare phases of a feedback clock signal and the reference clock signal; a control voltage adjustment unit to generate a second control signal, the voltage level of the second control signal adjusted by the first control signal; and an oscillation unit that includes a plurality of delay stages. The oscillation unit forms an oscillation loop having delay stages selected from the plurality of delay stages. The number of delay stages included in the oscillation loop may be determined by a loop selection unit. The loop selection unit identifies an output signal of a delay stage having a predetermined phase difference with respect to the reference clock signal and activates a corresponding loop selection signal from a plurality of loop selection signals to select the delay stages included in the oscillation loop. The oscillation unit further locks the looping signal to the reference clock signal according to the voltage level of the second control signal.

Another aspect of the invention is a clock locking method for generating an output clock signal locked to a reference locking signal in an oscillation unit. The clock locking method includes receiving input signals and delaying the input signals by a response delay time to generate a plurality of output signals. The method further includes selecting an output signal from the plurality of output signals having a predetermined phase difference with respect to the reference clock signal.

### BRIEF DESCRIPTION OF THE DRAWINGS

The above and other features and advantages of embodiments of the invention will become readily apparent by reference to the following detailed description when considered in conjunction with the accompanying drawings, in which:

FIG. 1 is a diagram of a conventional phase-locked loop circuit;

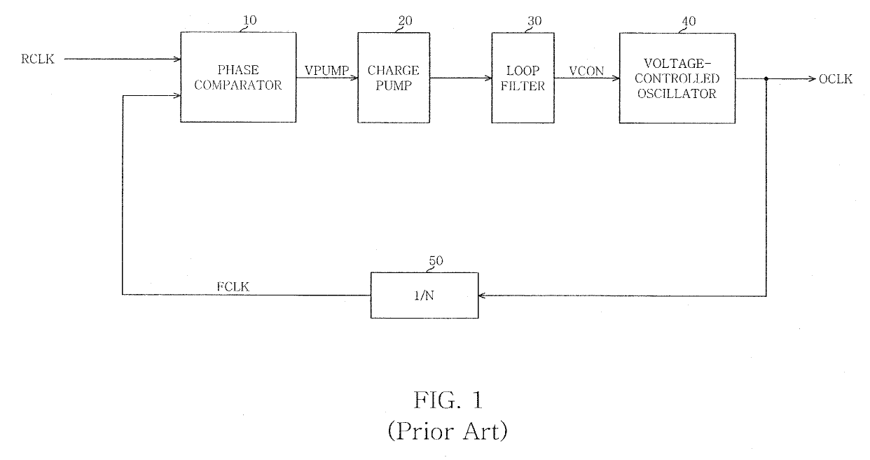

FIG. 2 is a schematic block diagram of one embodiment of a locked loop circuit according to principles of the invention;

FIG. 3 is a simplified circuit diagram of the initialization block of FIG. 2;

FIG. 4 is a timing diagram showing principal signals of the initialization block of FIG. 3;

FIG. 5 is a simplified circuit diagram of the oscillation block of FIG. 2;

FIG. 6 is a block diagram of the delay means of FIG. 5;

FIG. 7 is a block diagram of the loop selection unit of FIG. 2;

FIG. 8 is a diagram showing the transition detection block of FIG. 7;

FIG. 9 is a timing diagram showing an example activation of a loop selection signal from the loop selection signals of FIG. 2;

FIG. 10 is a diagram showing an example of the formation of an oscillation loop in the oscillation block of FIG. 5;

FIG. 11 is a diagram showing a procedure of finely locking an output clock signal in FIG. 2; and

FIG. 12 is a diagram showing effects obtained by the locked loop circuit of the invention.

### DESCRIPTION OF THE PREFERRED EMBODIMENTS

As will be apparent to those skilled in the art, the invention as described herein may be embodied in many different forms and should not be construed as limited to the specific embodiments set forth herein. Rather, these embodiments are provided so that this disclosure will fully convey the principles of the invention.

Reference should now be made to the drawings, in which the same reference numerals are used throughout the different drawings to designate the same or similar components. In the following description of embodiments of the invention, detailed descriptions of related well-known functions and construction may be omitted if it is determined that the detailed descriptions may make the gist of the invention unclear.

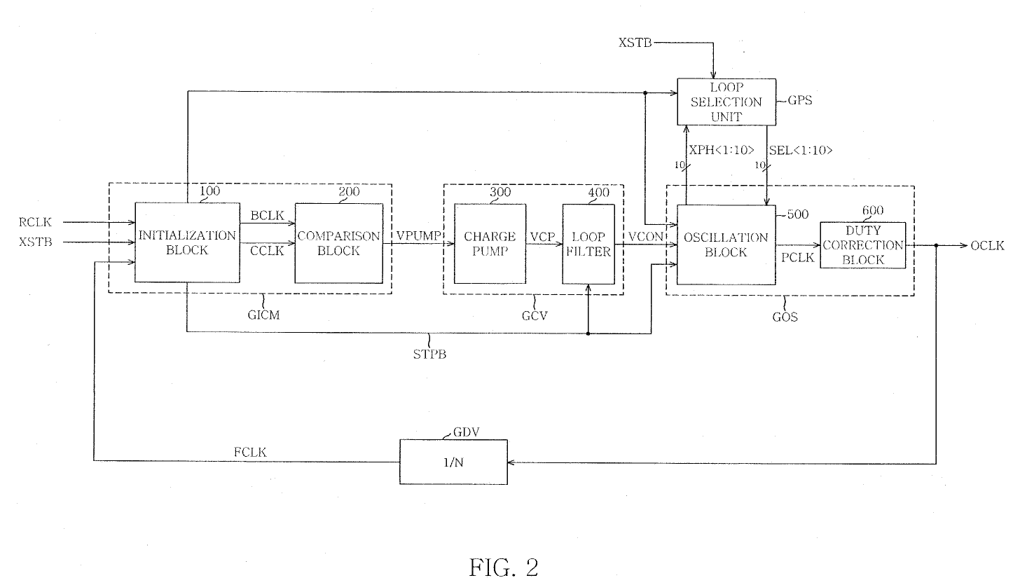

FIG. 2 is a schematic block diagram of one embodiment of a locked loop circuit according to principles of the invention. In FIG. 2, a Phase Locked Loop (PLL) circuit is shown merely as an example, and the scope of the invention is not limited to this example. Moreover, it should be apparent that the scope of the invention can be applied to various types of locked loop circuits, such as a Delay Locked Loop (DLL).

The locked loop circuit of FIG. 2 preferably generates an output clock signal OCLK locked to a reference clock signal RCLK in response to a start pulse signal XSTB. That is, the locked loop circuit starts to perform a locking operation in response to the generation of the start pulse signal XSTB.

The locked loop circuit may include an initialization and phase comparison unit GICM, a control voltage adjustment unit GCV, a voltage-controlled oscillation unit GOS, and a loop selection unit GPS. The initialization and phase comparison unit GICM preferably compares the phases of a feedback clock signal FCLK and a reference clock signal to generate a pumping control signal VPUMP (also referred to as a first control signal). In this embodiment, the feedback clock signal FCLK may be obtained by dividing the output clock signal OCLK through a divider GDV and preferably has a frequency that is 1/N times the frequency of the output clock signal OCLK. Therefore, the initialization and phase comparison unit GICM ultimately compares the phases of the output clock signal OCLK and the reference clock signal RCLK.

The initialization and phase comparison unit GICM may include an initialization block 100 and a comparison block 200. Preferably, the initialization block 100 generates a setup control signal STPB. The logic state of the setup control signal STPB preferably determines whether the locked loop circuit performs a coarse locking or a fine locking procedure. In one embodiment, the setup control signal STPB may be set to a logic L state during a predetermined coarse locking interval (for example, two clock periods) in response to the generation of the start pulse signal XSTB.

The comparison block 200 of the initialization and phase comparison unit GICM preferably generates the pumping control signal VPUMP. Based on comparison results obtained by the comparison block 200, the logic state of the pumping control signal VPUMP may be controlled. For example, if the phase of the feedback clock signal FCLK is leading the phase of the reference clock signal RCLK, the pumping control signal VPUMP may be set to a logic H state. On the other hand, if the phase of the feedback clock signal FCLK is lagging the phase of the reference clock signal RCLK, the pumping control signal VPUMP may be set to a logic L state.

The control voltage adjustment unit GCV preferably receives the pumping control signal VPUMP and generates an oscillation control signal VCON (also referred to as a second control signal). The voltage level of the oscillation control signal VCON may be adjusted depending on the logic state of the pumping control signal VPUMP. For example, if the logic state of the pumping control signal VPUMP transitions to a logic H state, the voltage level of the oscillation control signal VCON may be decreased, whereas if the logic state of the pumping control signal VPUMP transitions to a logic L state, the voltage level of the oscillation control signal VCON may be increased.

The oscillation control signal VCON is preferably provided to the voltage-controlled oscillation unit GOS. The voltage level of the oscillation control signal VCON may be initialized in response to the activation of the setup control signal STPB. In one embodiment, the locked loop circuit performs the coarse locking of the output clock signal OCLK while the logic state of the setup control signal STPB sent to the voltage-controlled oscillation unit GOS is set to a logic L state. The locked loop circuit then performs the fine locking of the output clock signal OCLK after the logic state of the setup control signal STPB is set to a logic H state.

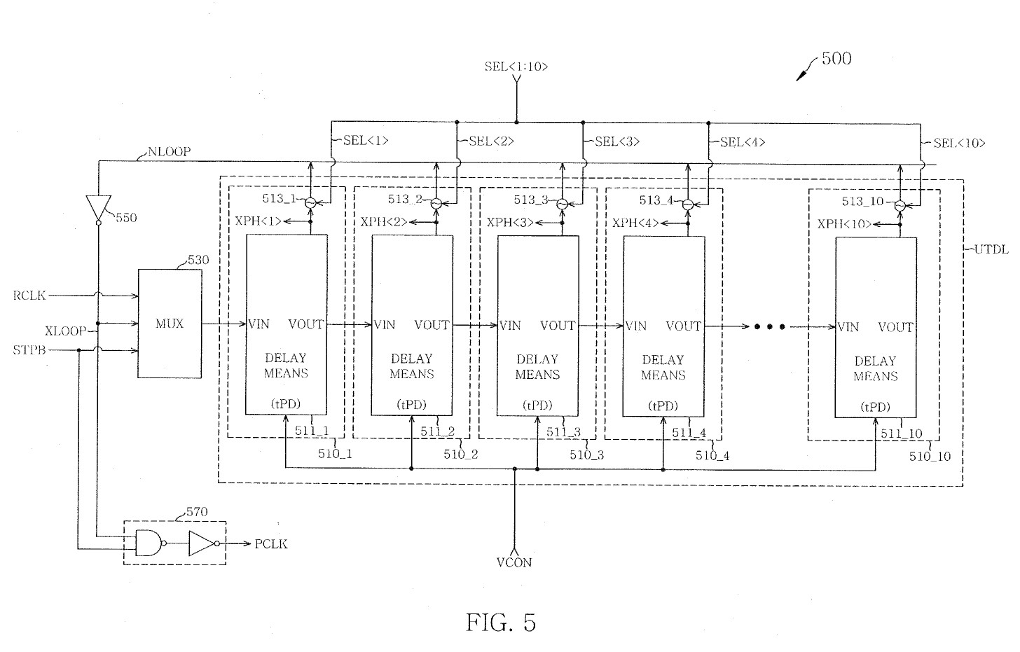

The voltage-controlled oscillation unit GOS preferably forms an oscillation loop and may include a plurality of delay stages (shown in FIG. 5) connected in a chain structure. The number of delay stages included in the oscillation loop may be determined according to which one of a plurality of loop selection signals SEL<1:10> is activated. Preferably, the coarse locking of the output clock signal OCLK is determined by the delay stages included in the oscillation loop. Further, the fine locking of the output clock signal OCLK may then be performed by adjusting the voltage level of the oscillation control signal VCON provided to the voltage-controlled oscillation unit GOS.

The loop selection unit GPS selects a signal to be activated from the plurality of loop selection signals SEL<1:10>. The loop selection unit GPS receives phase clock signals XPH<1:10> from the voltage-controlled oscillation unit GOS. Preferably, the phase clock signals XPH<1:10> have almost the same phases as the output signals of respective delay stages in the voltage-controlled oscillation unit GOS. The loop selection unit GPS detects the activation of the phase clock signals XPH<1:10> and then identifies a phase clock signal XPH<1:10> having a predetermined phase difference (for example, ½ period) with respect to the reference clock signal RCLK.

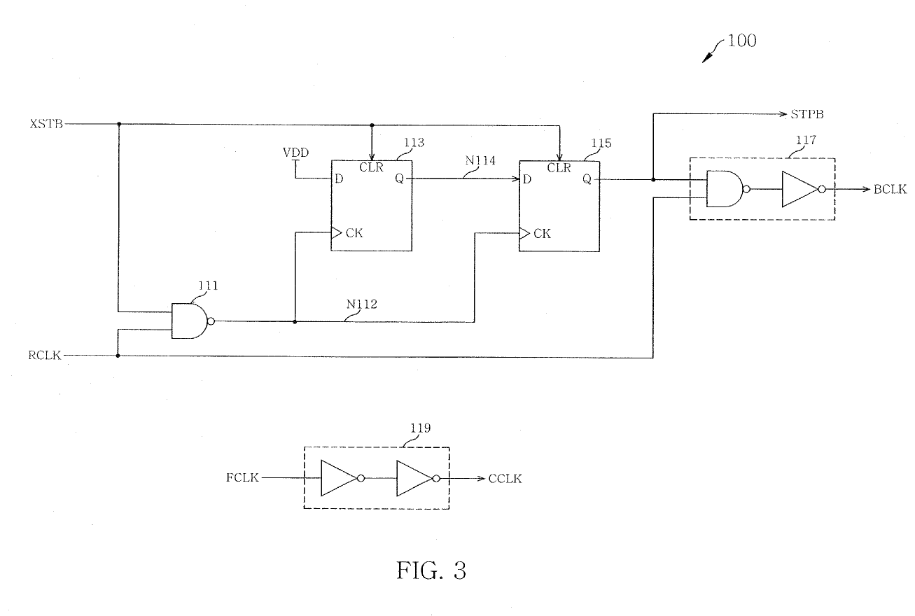

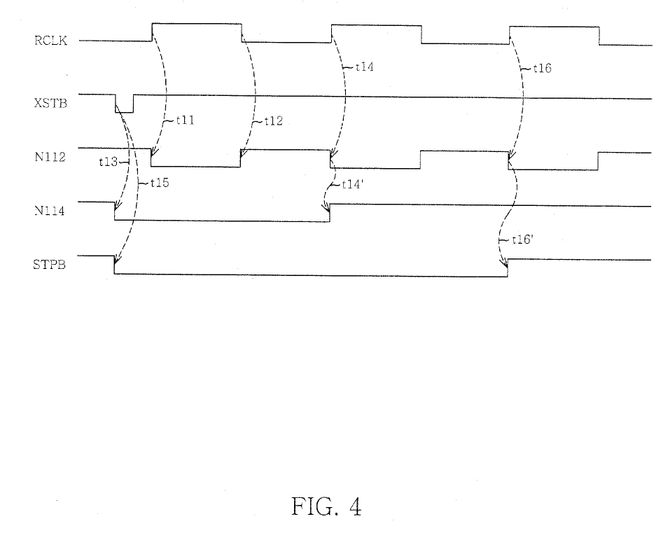

FIG. 3 is a simplified circuit diagram of the initialization block 100 of FIG. 2. FIG. 4 is a timing diagram showing the principal signals of the initialization block 100 of FIG. 3. Referring to FIGS. 3 and 4, the initialization block 100 preferably includes an initial logic gate 111, a first initial flip-flop 113 and a second initial flip-flop 115. Preferably, the initial logic gate 111 is a NAND gate for receiving the start pulse signal XSTB and the reference clock signal RCLK as input signals. Therefore, the initial logic gate 111 inverts the logic state of the reference clock signal RCLK while the start pulse signal XSTB is in a logic H state (refer to t11 and t12 of FIG. 4).

The first initial flip-flop 113 receives a supply voltage VDD through an input terminal D and receives the output signal N112 of the initial logic gate 111 through a clock terminal CK. Therefore, the output signal N114 of the first initial flip-flop 113 is initialized to a logic L state in response to the activation of the start pulse signal XSTB to a logic L state (t13 of FIG. 4), and is set to a logic H state in response to the end of the first clock cycle of the reference clock signal RCLK generated after initialization (refer to t14 and t14′ of FIG. 4).

The second initial flip-flop 115 receives the output signal N114 of the first initial flip-flop 113 through an input terminal D and receives the output signal N112 of the initial logic gate 111 through a clock terminal CK. Therefore, the setup signal STPB, which is the output signal of the second initial flip-flop 115, is set to a logic L state in response to the activation of the start pulse signal XSTB to a logic L state (refer to t15 of FIG. 4).

Further, the setup signal STPB is set to a logic H state in response to the end of the second clock cycle of the reference clock signal RCLK and after the output signal N114 of the first initial flip-flop 113 has been set to a logic H state (refer to t16 and t16′ of FIG. 4).

Consequently, the setup control signal STPB is set to a logic H state after an interval ranging from the generation of the start pulse signal XSTB to the end of the second clock cycle of the reference clock signal RCLK. In other words, the setup control signal STPB is set to a logic L state during the interval ranging from the generation of the start pulse signal XSTB to the end of the second clock cycle of the reference clock signal RCLK.

Referring to FIG. 3, the initialization block 100 preferably includes a buffering means 117 and a delay reflection means 119. The buffering means 117 may be enabled in response to the setup control signal STPB being set to a logic H state. The buffering means 117 preferably buffers the reference clock signal RCLK and generates a buffered clock signal BCLK provided to the comparison block 200 of FIG. 2.

The delay reflection means 119 preferably delays the feedback clock signal FCLK by a predetermined delay reflection time and generates a comparative clock signal CCLK provided to the comparison block 200. The delay reflection time of the delay reflection means 119 reflects the delay time caused by the buffering means 117.

The comparison block 200 compares the phases of the buffered clock signal BCLK and the comparative clock signal CCLK, thus comparing the phases of the reference clock signal RCLK and the feedback clock signal FCLK with each other.

Referring to FIG. 2 again, the control voltage adjustment unit GCV may include a charge pump 300 and a loop filter 400. The charge pump 300 preferably generates a charge signal VCP having a voltage level controlled by the pumping control signal VPUMP.

The loop filter 400 preferably receives the charge signal VCP and passes the low frequency component of the charge signal VCP to generate the oscillation control signal VCON. The voltage level of the oscillation control signal VCON may be initialized in response to the state of the setup control signal STPB, as described above.

Still referring to FIG. 2, the voltage-controlled oscillation unit GOS includes an oscillation block 500 and, preferably, further includes a duty correction block 600. The oscillation block 500 provides a preliminary clock signal PCLK to the duty correction block 600. The period of the preliminary clock signal PCLK may be controlled depending on the voltage level of the oscillation control signal VCON. The duty correction block 600 preferably corrects the duty cycle of the preliminary clock signal PCLK to generate the output clock signal OCLK.

FIG. 5 is a simplified circuit diagram of the oscillation block 500 of FIG. 2. Referring to FIG. 5, the oscillation block 500 preferably includes a loop node NLOOP, a delay unit UTDL including a plurality of delay stages 510₁₃ i (i=1 to 10), and a multiplexer (MUX) 530. Preferably, the oscillation block 500 further includes a preliminary clock generation means 570.

Each of the delay stages 51_i preferably provides a corresponding phase clock signal XPH<i> to the loop node NLOOP in response to a corresponding loop selection signal SEL<i>. Each of the delay stages 510_i may include a delay means 511_i and a switch 513_i. The delay means 511_i may be connected in a chain structure. That is, the delay means 511_i receive the output signals of their previous delay means 511_(i−1) as input signals. The delay means 511_i provide their output signals to subsequent delay means 511_(i+1) as input signals. However, the input signal of the delay means 511_1 is provided by the MUX 530.

The output signal of the delay means 511_i may be delayed from the input signal by a response delay time tPD. In FIG. 5, the embodiment shown includes a plurality of delay means having the same response delay time tPD. However, it is apparent to those skilled in the art that the invention can also be implemented in embodiments in which the delay means have different response delay times.

Preferably, each of the delay means 511_i amplifies the swing range of the output signal to generate the corresponding phase clock signal XPH<i>. The delay means 511_i may then provide the phase clock signal XPH<i> to the loop selection unit GPS of FIG. 2. Preferably, the switch 513_i provides the corresponding phase clock signal XPH<i> to the loop node NLOOP in response to the corresponding loop selection signal SEL<i>.

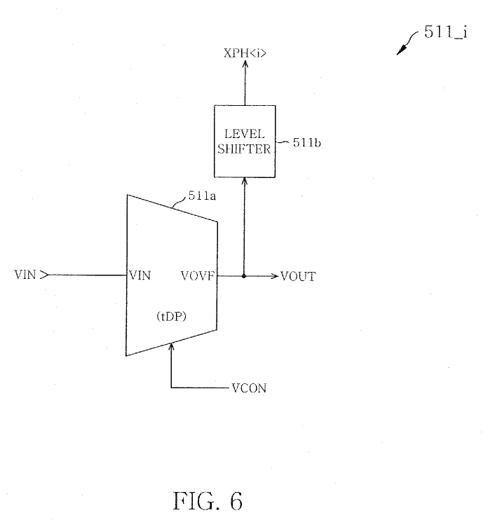

FIG. 6 is a block diagram of the delay means 511_i of FIG. 5. Referring to FIG. 6, each delay means 511_i may include a delay cell 511a and a level shifter 511b. Preferably, the delay cell 511a generates an output signal VOUT by delaying an input signal VIN by the response delay time tPD. The response delay time tPD may be controlled depending on the voltage level of the oscillation control signal VCON. Preferably, the level shifter 511b amplifies the voltage swing range of the output signal of the delay cell 511a and generates the phase clock signal XPH<i>.

Referring back to FIG. 5, the MUX 530 selectively outputs the reference clock signal RCLK and a looping signal XLOOP to the first delay stage 510_1 of the delay unit UTDL depending on the logic state of the setup control signal STPB. Preferably, the looping signal XLOOP is synchronized with a signal on the loop node NLOOP and may be obtained by inverting the signal on the loop node NLOOP. In one embodiment, while the setup control signal STPB is set to a logic L state, the MUX 530 may select and provide the reference clock signal RCLK to the first delay stage 510_1 of the delay unit UTDL. When the logic state of the setup control signal STPB is set to a logic H state, the MUX 530 may then select and provide the looping signal XLOOP to the first delay stage 510_1 of the delay unit UTDL. Thus, the locked loop circuit may perform coarse locking when the MUX 530 selects and provides the reference clock signal RCLK to the first delay stage 510_1 of the delay unit UTDL. Thereafter, the locked loop circuit may perform fine locking when the MUX 530 selects and provides the looping signal XLOOP to the first delay stage 510_1 of the delay unit UTDL.

The preliminary clock generation means 570 preferably buffers the looping signal XLOOP and generates the preliminary clock signal PCLK. The preliminary clock generation means 570 may be enabled in response to the setup control signal STPB being set to a logic H state.

Referring back to FIG. 2, the loop selection unit GPS detects the activation of the phase clock signals XPH<1:10> provided by the voltage-controlled oscillation unit GOS and then activates a loop selection signal SEL<1:10> selected from the loop selection signals SEL<1:10>, as described above.

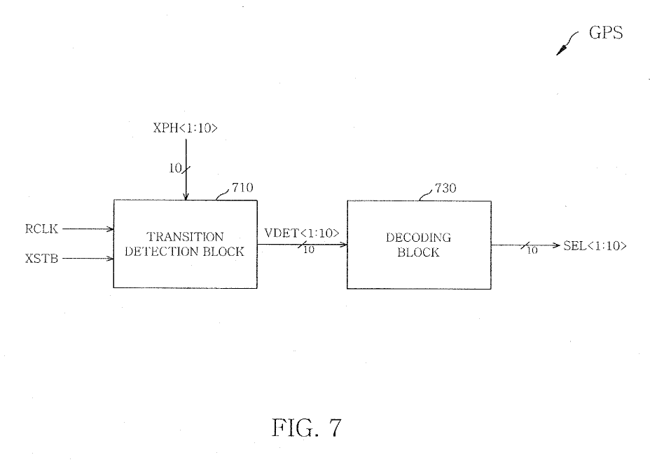

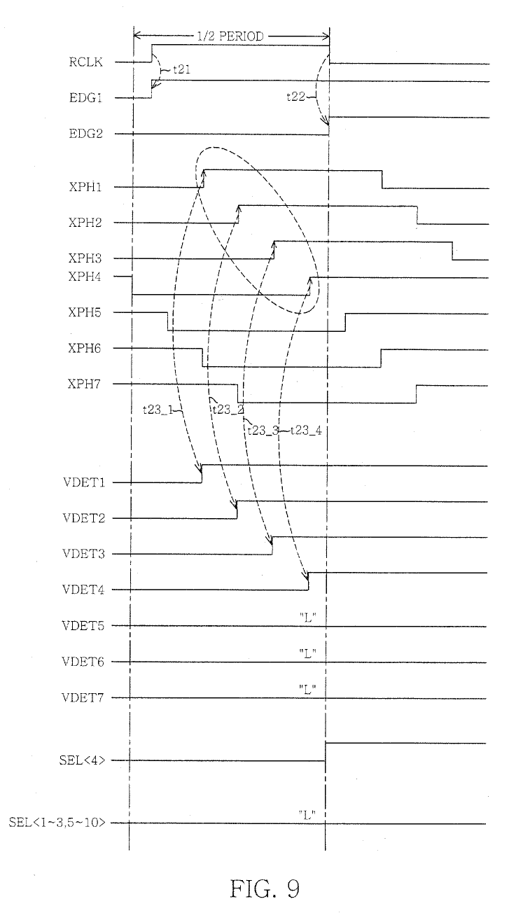

FIG. 7 is a block diagram of the loop selection unit GPS of FIG. 2. Referring to FIG. 7, the loop selection unit GPS includes a transition detection block 710 and a decoding block 730. The transition detection block 710 receives the phase clock signals XPH<1:10>and generates transition verification signals VDET<1:10>. Preferably, the transition verification signals VDET<1:10> are initialized to a logic L state in response to the generation of the start pulse signal XSTB. The transition verification signals VDET<1:10> may be set to a logic H state when the phase clock signals XPH<1:10>, generated during a ½ period of the reference clock signal RCLK, are set to a logic H state (refer to FIG. 9).

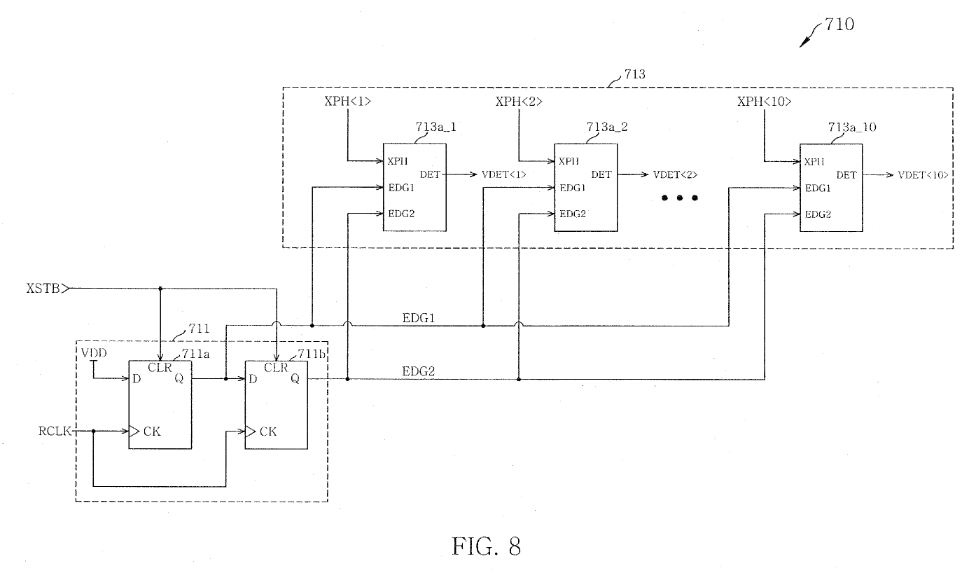

FIG. 8 is a diagram showing the transition detection block 710 of FIG. 7. Referring to FIG. 8, the transition detection block 710 preferably includes a reference setting unit 711 and a transition verification unit 713. The reference setting unit 711 preferably receives the reference clock signal RCLK and generates first and second reference setting signals EDGI and EDG2. The first and second reference setting signals EDG1 and EDG2 may be initialized to a logic L state in response to the generation of the start pulse signal XSTB.

The reference setting unit 711 may include first and second reference flip-flops 711a and 711b. The first reference flip-flop 711a receives the reference clock signal RCLK through a clock terminal CK and generates the first reference setting signal EDG1. The first reference setting signal EDG1 may be set to a logic H state in response to the leading edge of the first clock of the reference clock signal RCLK generated after the start pulse signal XSTB has been generated (refer to t21 of FIG. 9).

The second reference flip-flop 711b receives the reference clock signal RCLK through a clock terminal CK, and generates the reference setting signal EDG2. The second reference setting signal EDG2 may be set to a logic H state in response to the lagging edge of the first clock of the reference clock signal RCLK generated after the start pulse signal XSTB has been generated (refer to t22 of FIG. 9).

The transition verification unit 713 may include a plurality of transition verification means 713a i (i=1 to 10) for generating respective transition verification signals VDET<i>. The transition verification signals VDET<i>may be activated when the respective phase clock signals XPH<i>, generated between the activation of the first reference setting signal EDG1 and the activation of the second reference setting signal EDG2, transition to a logic H state.

FIG. 9 is a timing diagram showing an example activation of a loop selection signal from the loop selection signals of FIG. 2. Referring to FIG. 9, during the time period between the activation of the first reference setting signal EDG1 and the activation of the second reference setting signal EDG2, the first to fourth phase clock signals XPH<1> to XPH<4> are activated. The first to fourth transition verification signals VDET<1> to VDET<4> corresponding to the first to fourth phase clock signals XPH<1> to XPH<4> are also activated (refer to t23_1 to t23_4 of FIG. 9).

Referring back to FIG. 7, the decoding block 730 preferably receives the transition verification signals VDET<1:10> and generates the loop selection signals SEL<1:10>. Preferably, the loop selection signals SEL<1:10> are selectively activated in response to the transition verification signals VDET<1:10>. That is, a loop selection signal SEL<i> may be activated depending on the logic states of the corresponding transition verification signal VDET<i> of the delay stage 510_i and the transition verification signal VDET<i−1>or VDET<i+1> of the delay stage 510_(i+1) or 510_(i+1) adjacent to the delay stage 510_i.

In this embodiment, a loop selection signal SEL<i> is preferably activated depending on the logic states of the transition verification signal VDET<i> of the delay stage 510_i corresponding to the loop selection signal SEL<i> and the transition verification signal VDET<i+1>of the delay stage 510_(i+1) subsequent to the delay stage 510_i.

In FIG. 9, for example, the fourth transition verification signal VDET<4> is set to a logic H state, whereas the fifth transition verification signal VDET<5> is maintained at a logic L state. The phase clock signal XPH<4> of the fourth delay stage 510_4 (in FIG. 5) or the phase clock signal XPH<5> of the fifth delay stage 510_5 has a phase difference of about ½ period with respect to the reference clock signal RCLK. Thus, the loop selection signal SEL<4> for selecting the fourth delay stage 510_4 is activated.

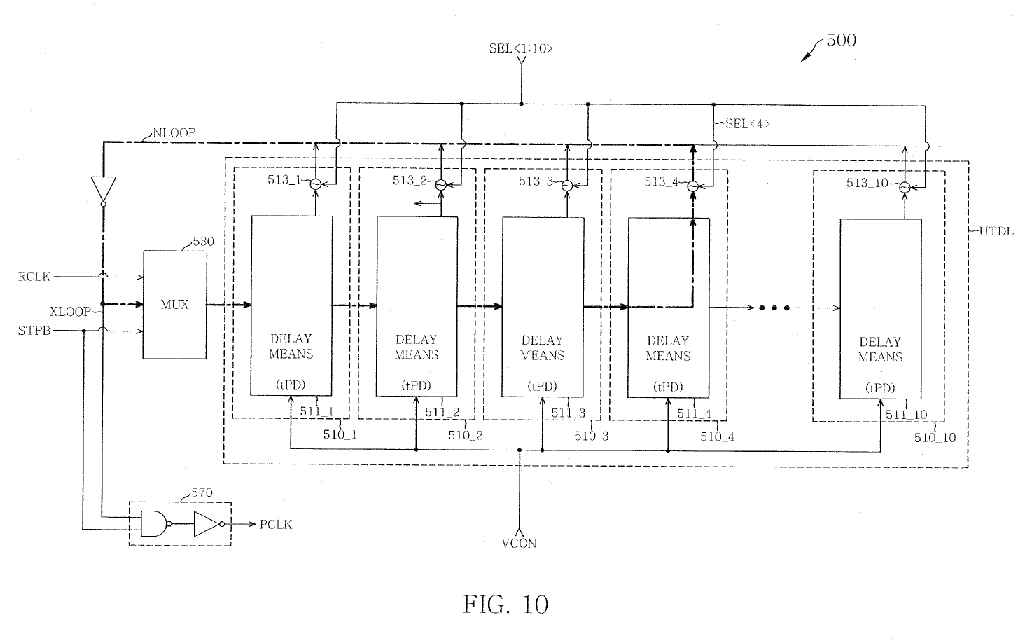

FIG. 10 is a diagram showing an example of the formation of an oscillation loop in the oscillation block 500 of FIG. 5. Referring to FIG. 10, an oscillation loop, which is a closed circuit, is formed and performs a coarse locking. The number of delay stages included in the oscillation loop preferably depends on the selection of the loop selection signals SEL<1:10>. Thus, when the loop selection signal SEL<4> is activated, the oscillation loop then includes the first to fourth delay stages 510_1 to 510_4, the looping node NLOOP, the inverter 550, and the MUX 530. The looping signal XLOOP, obtained by inverting the signal on the loop node NLOOP through the inverter 550, is coarsely locked to the reference clock signal RCLK. Ultimately, the output clock signal OCLK is then coarsely locked to the reference clock signal RCLK.

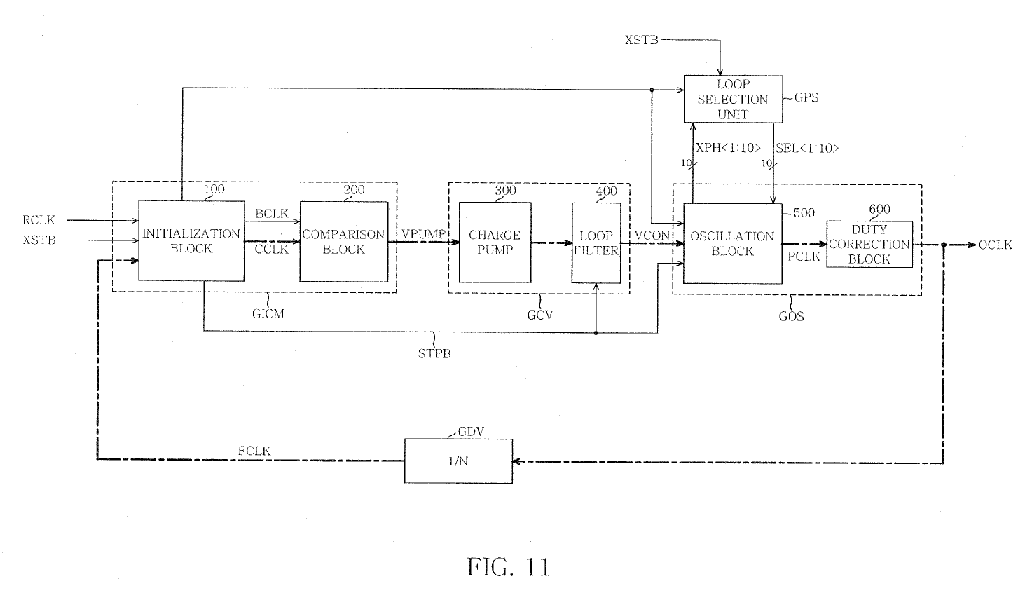

Thereafter, finely locking the output clock signal OCLK to the reference clock signal RCLK is performed through a path including the comparison block 200, the charge pump 300 and the oscillation block 500, as shown in FIG. 11.

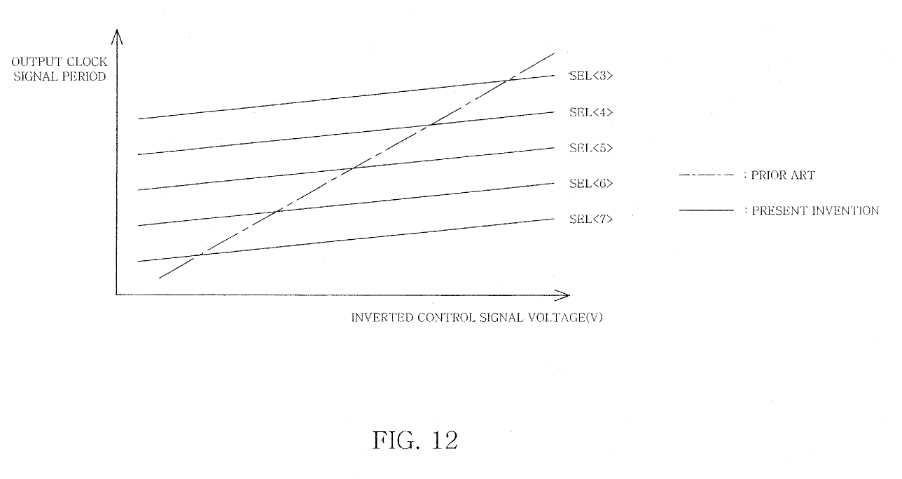

FIG. 12 is a diagram showing effects obtained by the locked loop circuit according to principles of the invention. Referring to FIG. 12, the period of the output clock signal OCLK may be adjusted depending on the number of delay stages included in the oscillation loop. Thus, the period of the output clock signal OCLK may be controlled by the selection of the loop selection signals SEL<1:10>, so that the coarse locking speed of the output clock signal OCLK may be improved. Moreover, delay stages having a low gain may be employed and the jitter of the output clock signal OCLK may be reduced. Thus, the fine locking of the output clock signal OCLK may also be facilitated.

Although preferred embodiments of the invention have been disclosed for illustrative purposes, those skilled in the art will appreciate that various modifications, additions, and substitutions are possible without departing from the scope and spirit of the invention as disclosed in the accompanying claims.

1. A circuit for generating an output clock signal locked to a reference clock signal, comprising:
an initialization and phase comparison unit adapted to generate a first control signal according to a comparison of phases of a feedback clock signal and the reference clock signal;
a control voltage adjustment unit adapted to generate a second control signal having a voltage level adjusted by the first control signal;
an oscillation unit adapted to form an oscillation loop having delay stages selected from a plurality of delay stages, the selected delay stages locking the output clock signal to the reference clock signal.

2. The circuit according to claim 1, further comprising:
a loop selection unit adapted to identify an output signal of a delay stage in the oscillation unit having a predetermined phase difference with respect to the reference clock signal and activate a corresponding loop selection signal from a plurality of loop selection signals to select the delay stages included in the oscillation loop.

3. The circuit according to claim 1, wherein the oscillation unit is further adapted to lock the output clock signal to the reference clock signal according to the voltage level of the second control signal.

4. The circuit according to claim 3, wherein the initialization and phase comparison unit is further adapted to generate a setup control signal for controlling whether the output clock signal is locked to the reference clock signal by the oscillation loop or according to the voltage level of the second control signal.

5. The circuit according to claim 1, wherein the plurality of delay stages are connected in a chain structure and adapted to generate a plurality of output signals and respective phase clock signals, the phase clock signals having phases corresponding to the respective output signals and the output signals provided to subsequent delay stages.

6. The circuit according to claim 1, further comprising:
a multiplexer to selectively provide the reference clock signal or a looping signal to a first delay stage of the plurality of delay stages according to a logic state of the setup control signal, the looping signal generated by the oscillation loop and locked to the reference clock signal.

7. The circuit according to claim 6, wherein each of the delay stages comprises:
delay means to receive an input signal from the multiplexer or a previous delay stage and provide an output signal to a subsequent delay stage, the delay means further adapted to generate a phase clock signal having a phase corresponding to the output signal.

8. The circuit according to claim 7, wherein each of the delay stages further comprises:
a switch to provide the phase clock signal to a loop node in the oscillation loop in response to a corresponding loop selection signal.

9. The circuit according to claim 7, wherein the delay means comprises:
a delay cell to generate the output signal by delaying the input signal by a response delay time; and
a level shifter to generate the phase clock signal by amplifying a voltage swing range of the output signal of the delay cell.

10. The circuit according to claim 2, wherein the loop selection unit comprises:
a transition detection block to generate transition verification signals, the transition verification signals activated to correspond to activation of respective phase clock signals generated by the plurality of delay stages; and
a decoding block to activate the loop selection signal depending on logic states of the transition verification signals.

11. The circuit according to claim 10, wherein the loop selection signal is activated depending on whether a transition verification signal of the delay stage corresponding to the loop selection signal and a transition verification signal of another delay stage adjacent to the delay stage are activated.

12. The circuit according to claim 10, wherein the transition detection block comprises:
a reference setting unit adapted to generate first and second reference setting signals so as to set a reference period; and
a transition verification unit including a plurality of transition verification means adapted to generate respective transition verification signals that are activated in response to activation of respective phase clock signals generated during the reference period.

13. A circuit for generating an output clock signal locked to a reference clock signal, comprising:
an oscillation unit adapted to form an oscillation loop having delay stages selected from a plurality of delay stages, the number of delay stages included in the oscillation loop depending on a selected one of a plurality of loop selection signals; and
a loop selection unit adapted to select the one selection signal corresponding to an output signal of one of the delay stages that has a predetermined phase difference with respect to the reference clock signal.

14. The circuit according to claim 13, wherein the oscillation unit is further adapted to adjust a period of the looping signal depending on a voltage level of a second control signal, the voltage level adjusted by a first control signal according to a phase comparison of the output clock signal and the reference clock signal.

15. The circuit according to claim 13, wherein the plurality of delay stages are connected in a chain structure and adapted to generate a plurality of output signals and respective phase clock signals, the phase clock signals having phases corresponding to respective output signals and the output signals provided to subsequent delay stages.

16. The circuit according to claim 15, further comprising:
a multiplexer adapted to selectively provide the reference clock signal or a looping signal to a first delay stage of the plurality of delay stages, the looping signal generated by the oscillation loop and locked to the reference clock signal.

17. The circuit according to claim 16, wherein each of the delay stages comprises:
delay means adapted to delay an input signal received from the multiplexer or a previous delay stage and provide an output signal to a subsequent delay stage, the delay means further adapted to generate a phase clock signal.

18. The circuit according to claim 17, wherein each of the delay stages further comprises:
a switch for providing the phase clock signal to a loop node in the oscillation loop in response to a corresponding loop selection signal.

19. The circuit according to claim 17, wherein the delay means comprises:
a delay cell adapted to delay the input signal by a response delay time; and
a level shifter adapted to amplify a voltage swing range of the output signal of the delay cell.

20. The circuit according to claim 13, wherein the loop selection unit comprises:
a transition detection block adapted to generate transition verification signals, the transition verification signals activated to correspond to activation of respective phase clock signals generated by the plurality of delay stages; and
a decoding block adapted to activate the loop selection signal selected depending on logic states of the transition verification signals.

21. The circuit according to claim 20, wherein the loop selection signal is activated depending on whether a transition verification signal of the delay stage corresponding to the loop selection signal and a transition verification signal of another delay stage adjacent to the delay stage are activated.

22. The circuit according to claim 20, wherein the transition detection block comprises:
a reference setting unit adapted to generate first and second reference setting signals so as to set a reference period; and
a transition verification unit including a plurality of transition verification means to generate respective transition verification signals that are activated in response to activation of respective phase clock signals generated during the reference period.

23. A method of generating an output clock signal locked to a reference clock signal in an oscillation unit, comprising:
receiving an input signal;
successively delaying the input signal by response delay times;
selecting one of the delayed input signals that has a predetermined phase difference with respect to the reference clock signal.

24. The method according to claim 23, wherein selecting one of the delayed input signals that has the predetermined phase difference with respect to the reference clock signal comprises:
generating a plurality of phase clock signals corresponding to the plurality of delayed input signals, the phase clock signals having almost the same phases as the delayed input signals;
generating a plurality of transition verification clock signals corresponding to activation of respective phase clock signals;
comparing logic states of the plurality of transition verification clock signals; and
activating a loop selection signal from a plurality of loop selection signals according to the logic states of the plurality of transition verification clock signals.

25. The method according to claim 23, wherein the response delay times are the same.

26. A circuit for generating an output clock signal locked to a reference clock signal, comprising:
an oscillation unit adapted to receive an input signal and generate a plurality of output signals;
a loop selection unit adapted to identify an output signal from the plurality of output signal having a predetermined phase difference with respect to the reference clock signal.

27. The circuit according to claim 26, wherein the oscillation unit comprises:
a plurality of delay stages, each delay stage delaying a received input signal by a response delay time to generate an output signal.

28. The circuit according to claim 26, wherein the oscillation unit is further adapted to lock the output clock signal to the reference clock signal according to a voltage level of a control signal, the voltage level controlled according to a phase comparison between the output clock signal and the reference clock signal.
